(19) United States
(12) Patent Application Publication
(10) Pub. No.: US 2017/0033780 A1
(43) Pub. Date: Feb. 2, 2017

(54) SEMICONDUCTOR DEVICE AND SEMICONDUCTOR PACKAGE USING THE SAME

(71) Applicant: SK hynix Inc., Icheon-si Gyeonggi-do (KR)

(72) Inventors: Sun Ki CHO, Icheon-si Gyeonggi-do (KR); Jong Joo SHIM, Icheon-si Gyeonggi-do (KR)

(21) Appl. No.: 14/958,239

(22) Filed: Dec. 3, 2015

(30) Foreign Application Priority Data
Jul. 27, 2015 (KR) 10-2015-0105903

(51) Int. Cl. H03K 5/24

(52) U.S. Cl. CPC H03K 5/2472

(57) ABSTRACT

A semiconductor device may include a comparator and a pad. The comparator may compare a voltage level of a reference node with a voltage level of a reference voltage to generate a code. The comparator may include an output driver modeling unit configured to adjust a current flowing to the reference node depending on a code value of the code to the reference node. The pad may be coupled to the reference node. A total impedance of the reference node, the output driver modeling unit, and components and signal lines coupled therebetween may correspond to a total impedance of the reference node, the pad, and components and signal lines coupled therebetween.

### CROSS-REFERENCES TO RELATED APPLICATION

The present application claims priority under 35 U.S.C. §119(a) to Korean application number 10-2015-0105903 filed on July 2015, in the Korean Intellectual Property Office, which is incorporated herein by reference in its entirety.

### BACKGROUND

1. Technical Field

Various embodiments relate generally to a semiconductor integrated circuit, and more particularly to a semiconductor device and a semiconductor package using the semiconductor device.

2. Related Art

A semiconductor device may include a comparator to check as to whether operations thereof are being carried out properly and characteristics of thereof meet standard requirements.

The semiconductor device may include various types of comparators to check characteristics of electrical circuits therein. For instance, the comparator may determine whether a voltage applied to a specific node is higher or lower than a predetermined voltage or a current flowing through a specific node is greater or less than a predetermined current.

Therefore, a stable, accurate operation of the comparator is the key to a stable, accurate operation of the semiconductor device.

### SUMMARY

According to example embodiments, there may be provided a semiconductor device. The semiconductor device may include a comparator and a pad. The comparator may compare a voltage level of a reference node with a voltage level of a reference voltage to generate a code. The comparator may include an output driver modeling unit configured to supply a current corresponding to a code value of the code to the reference node. The pad may be electrically connected with the reference node. An impedance between the reference node and the output driver modeling unit may correspond to an impedance between the reference node and the pad.

According to example embodiments, there may be provided a semiconductor package. The semiconductor package may include a package substrate and a semiconductor device. The semiconductor device may be arranged on the package substrate. An impedance between a reference node and the semiconductor device may correspond to an impedance between the reference node and a ball of the package substrate.

### BRIEF DESCRIPTION OF THE DRAWINGS

Example embodiments can be understood in more detail from the following detailed description taken in conjunction with the accompanying drawings. FIGS. 1 to 5 represent non-limiting example embodiments as described herein.

FIG. 1 is a block diagram illustrating a semiconductor device in accordance with example embodiments;

FIG. 2 is a block diagram illustrating a semiconductor device in accordance with example embodiments;

FIG. 3 is a block diagram illustrating a semiconductor package using a semiconductor device in accordance with example embodiments;

FIG. 4 is a block diagram illustrating a semiconductor device in accordance with example embodiments; and

FIG. 5 is a block diagram illustrating a semiconductor package using a semiconductor device in accordance with example embodiments.

### DETAILED DESCRIPTION

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

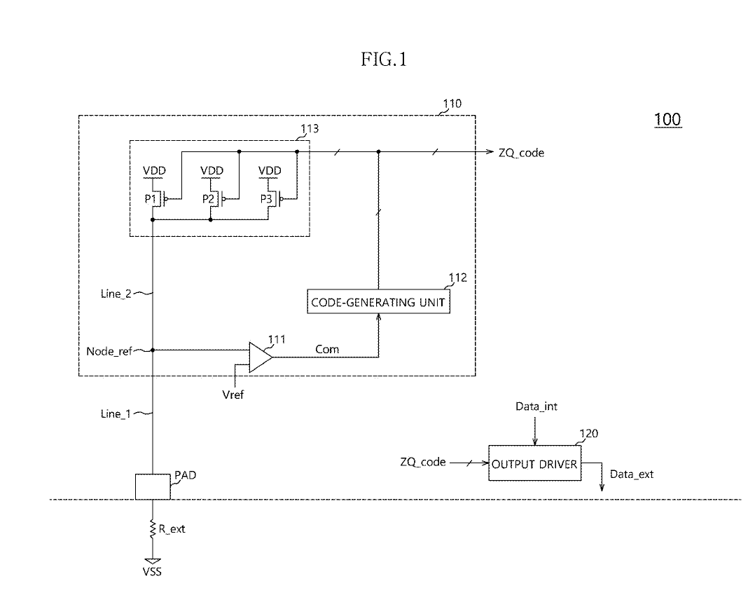

FIG. 1 is a block diagram illustrating a semiconductor device in accordance with example embodiments.

Referring to FIG. 1, a semiconductor device 100 of this example embodiment may include a comparator 110, an output driver 120, and a pad PAD. The pad PAD may be connected to an external resistance R_ext.

The comparator 110 may be coupled to the pad PAD through a first line Line_1.

The pad PAD may be coupled between the first line Line_1 and the external resistance R_ext arranged outside the semiconductor device 100.

The external resistance R_ext may have a first end coupled to the pad PAD, and a second end coupled to a ground terminal VSS.

The comparator 110 may include a comparing unit 111, a code-generating unit 112, and an output driver modeling unit 113.

The comparing unit 111 may compare a voltage level of a reference node Node_ref with a voltage level of a reference voltage Vref to generate a comparison signal Com. For example, if the voltage level of the reference node Node_ref is higher than the voltage level of the reference voltage Vref, the comparing unit 111 may enable the comparison signal Com. In contrast, if the voltage level of the reference node Node_ref is lower than the voltage level of the reference voltage Vref, the comparing unit 111 may disable the comparison signal Com.

The code-generating unit 112 may generate a code ZQ_code in response to the comparison signal Com. For example, if the comparison signal Com is enabled, the code-generating unit 112 may increase a code value of the code ZQ_code. In contrast, if the comparison signal Com is disabled, the code-generating unit 112 may decrease a code value of the code ZQ_code.

The output driver modeling unit 113 may adjust a current flowing to the reference node Node_ref or a voltage at the reference node Node_ref in response to the code ZQ_code. For example, the output driver modeling unit 113 may increase the voltage at the reference node Node_ref as the code value of the code ZQ_code decreases, or the output driver modeling unit 113 may increase the current flowing to the reference node Node_ref as the code value of the code ZQ_code decreases. The output driver modeling unit 113 may decrease the voltage at the reference node Node_ref as the code value of the code ZQ_code increases, or the output driver modeling unit 113 may decrease the current flowing to the reference node Node_ref as the code value of the code ZQ_code increases.

The output driver modeling unit 113 may include a first transistor P1, a second transistor P2, and a third transistor P3. The first transistor P1 may include a gate that is inputted with a first bit of the code ZQ_code, and a source that is inputted with an external voltage VDD. The second transistor P2 may include a gate that is inputted with a second bit of the code ZQ_code, and a source that is inputted with the external voltage VDD. The third transistor P3 may include a gate that is inputted with a third bit of the code ZQ_code, and a source that is inputted with the external voltage VDD. The first to third transistors P1, P2, and P3 may include drains coupled in common. A node coupled to the drains of the first to third transistors P1, P2, and P3 in common may be coupled to the reference node Node_ref through a second line Line_2. The first line Line_1 may have a length the same or substantially the same as a length of the second line Line_2.

The output driver 120 may output internal data Data_int as output data Data_ext in response to the code ZQ_code. For example, the output driver 120 may drive the internal data Data_int using a driving force corresponding to the code value of the code ZQ_code to output the output data Data_ext.

Hereinafter, operations of the semiconductor device 100 of this example embodiment may be illustrated in detail.

The semiconductor device 100 may be coupled to an external device, and signals are exchanged between the semiconductor device and the external device.

In order to minimize signal reflections, the semiconductor device 100 may perform an impedance matching operation such as a ZQ calibration operation.

The impedance matching operation may determine a driving force of the output driver 120 for outputting signals such as data to the external device depending on a predetermined resistance value (e.g., a level of the external resistance R_ext).

The comparator 110 may generate the code ZQ_code having the code value corresponding to the external resistance R_ext.

The output driver 120 may drive the internal data Data_int using the driving force corresponding to the code value of the code ZQ_code to output the external data Data_ext.

Hereinafter, operations for generating the code ZQ_code by the comparator 110 will be described in detail.

The comparator 110 may include the comparing unit 111, the code-generating unit 112, and the output driver modeling unit 113.

The comparing unit 111 may compare the voltage level of the reference node Node_ref with the voltage level of the reference voltage Vref to generate the comparison signal Com.

The code-generating unit 112 may generate the code ZQ_code in response to the comparison signal Com.

The output driver modeling unit 113 may adjust the current flowing to the reference node Node_ref or the voltage at the reference node Node_ref in response to the code ZQ_code.

The comparator 110 may generate the code value of the code ZQ_code at which the reference voltage Vref has the same value or substantially the same value as the reference node Node_ref. The voltage level of the reference node Node_ref may be determined depending on a ratio between the current flowing from output driver modeling unit 113 to the reference node Node_ref, which is determined by the code ZQ_code, and the current flowing from the reference node Node_ref to the external resistance R_ext. Thus, the code ZQ_code may have the code value corresponding to the value of the external resistance R_ext.

The reference node Node_ref may be a node that electrically connects the first line Line_1 and the second line Line_2 to one another. The first line Line_1 may be coupled between the pad PAD and the reference node Node_ref. The second line Line_2 may be coupled between the output driver modeling unit 113 and the reference node Node_ref. The pad PAD may be coupled to the external resistance R_ext.

Thus, the voltage level of the reference node Node_ref may be determined depending on the ratio between the current flowing to the reference node Node_ref through the second line Line_2 in accordance with the code value of the code ZQ_code and the current flowing to the external resistance R_ext through the first line Line_1.

That is, the voltage level of the reference node Node_ref may be determined depending on a ratio between a total impedance of the external resistance R_ext and the first line Line_1 and a total impedance of the output driver modeling unit 113 and the second line Line_2.

Therefore, when only the external resistance R_ext and the output driver modeling unit 113 are taken into account in determining the code ZQ_code, the impedance of the first line Line_1 may be the same or substantially the same as the impedance of the second line Line_2. That is, when the length of the first line Line_1 is the same or substantially the same as the length of the second line Line_2, the code ZQ_code may have the code value corresponding to the level of the external resistance R_ext.

As a result, because the first line Line_1 and the second line Line_2 may be formed simultaneously by a single process, the same lengths of the first line Line_1 and the second line Line_2 may mean that the first line Line_1 and the second line Line_2 have the same impedances as one another. The same impedances of the first line Line_1 and the second line Line_2 may provide the code ZQ_code with the code value corresponding to the level of the external resistance R_ext.

According to an example embodiment, the semiconductor device 100 may include the first line Line_1 coupled between the output driver modeling unit 113 and the reference node Node_ref, and the second line Line_2 coupled between the reference node Node_ref and the pad PAD. The length of the first line Line_1 may be the same or substantially the same as the length of the second line Line_2. The code ZQ_code for determining the driving force of the output driver modeling unit 113 may be generated by comparing the voltage level of the reference node Node_ref with the voltage level of the reference voltage Vref.

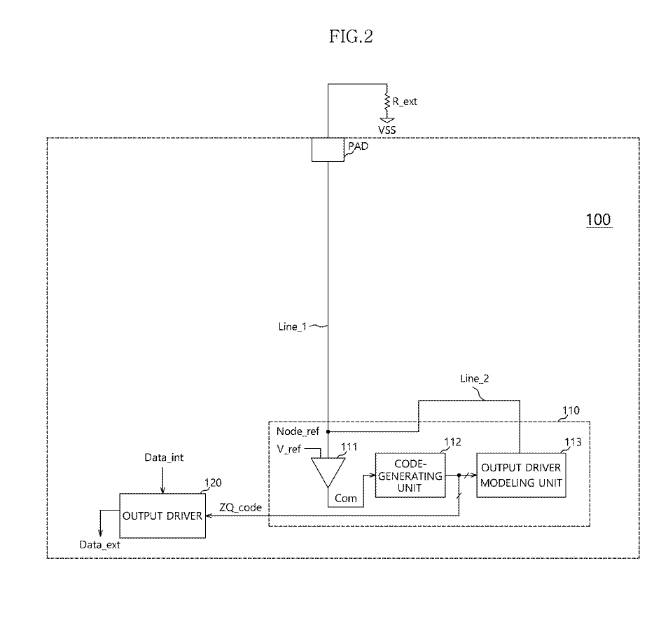

FIG. 2 is a block diagram illustrating a semiconductor device in accordance with example embodiments.

Referring to FIG. 2, a semiconductor device 100 in accordance with an embodiment may include a comparator 110, an output driver 120 and a pad PAD. The pad PAD may be coupled to an external resistance R_ext.

The comparator 110 may be coupled to the pad PAD through a first line Line_1.

The pad PAD may be coupled between the first line Line_1 and the external resistance R_ext arranged outside the semiconductor device 100.

The external resistance R_ext may have a first end coupled to the pad PAD and a second end coupled to a ground terminal VSS.

The comparator 110 may include a comparing unit 111, a code-generating unit 112, and an output driver modeling unit 113.

The comparing unit 111 may compare a voltage level of a reference node Node_ref with a voltage level of a reference voltage Vref to generate a comparison signal Com. For example, when the voltage level of the reference node Node_ref is higher than the voltage level of the reference voltage Vref, the comparing unit 111 may enable the comparison signal Com. In contrast, when the voltage level of the reference node Node_ref is lower than the voltage level of the reference voltage Vref, the comparing unit 111 may disable the comparison signal Com.

The code-generating unit 112 may generate a code ZQ_code in response to the comparison signal Com. For example, when the comparison signal Com is enabled, the code-generating unit 112 may increase a code value of the code ZQ_code. In contrast, when the comparison signal Com is disabled, the code-generating unit 112 may decrease a code value of the code ZQ_code.

The output driver modeling unit 113 may adjust a current flowing to the reference node Node_ref or a voltage at the reference node Node_ref in response to the code ZQ_code. For example, the output driver modeling unit 113 may increase the voltage at the reference node Node_ref as the code value of the code ZQ_code decreases, or the output driver modeling unit 113 may increase the current flowing to the reference node Node_ref as the code value of the code ZQ_code decreases. The output driver modeling unit 113 may decrease the voltage at the reference node Node_ref as the code value of the code ZQ_code increases, or the output driver modeling unit 113 may decrease the current flowing to the reference node Node_ref as the code value of the code ZQ_code increases.

The output driver modeling unit 113 in FIG. 2 and the output driver modeling unit 113 in FIG. 1 may have the same or very similar configuration.

The output driver 120 may output internal data Data_int as output data Data_ext in response to the code ZQ_code. For example, the output driver 120 may drive the internal data Data_int using a driving force corresponding to the code value of the code ZQ_code to output the output data Data_ext.

The semiconductor device in FIG. 2 and the semiconductor device in FIG. 1 may have the same or very similar configuration. In contrast, the pad PAD may be arranged at an end portion of the semiconductor device. The output driver 120 and the comparator 110 may be arranged at another end portion of the semiconductor device. Thus, the first line Line_1 coupled to the reference node Node_ref and the pad PAD may have a length longer than the length of the first line Line_1 in FIG. 1.

Therefore, the second line Line_2 coupled between the reference node Node_ref and the output driving modeling unit 113 may have a length the same or substantially the same as the length of the first line Line_1 in FIG. 2. Here, the shape of the second line Line_2 may be different from the shape of the second line Line_2 in FIG. 2.

Hereinafter, operations of the semiconductor device 100 of an embodiment will be described in detail.

The comparator 110 may generate the code ZQ_code having the code value corresponding to the external resistance R_ext.

The output driver 120 may drive the internal data Data_int using the driving force corresponding to the code value of the code ZQ_code to output the external data Data_ext.

Hereinafter, operations for generating the code ZQ_code by the comparator 110 will be described in detail.

The comparator 110 may include the comparing unit 111, the code-generating unit 112, and the output driver modeling unit 113.

The comparing unit 111 may compare the voltage level of the reference node Node_ref with the voltage level of the reference voltage Vref to generate the comparison signal Com.

The code-generating unit 112 may generate the code ZQ_code in response to the comparison signal Com.

The output driver modeling unit 113 may adjust the current flowing to the reference node Node_ref or the voltage at the reference node Node_ref in response to the code ZQ_code.

The comparator 110 may generate the code value of the code ZQ_code at which the reference voltage Vref has the same value or substantially the same value as the reference node Node_ref. The voltage level of the reference node Node_ref may be determined depending on a ratio between the current flowing from output driver modeling unit 113 to the reference node Node_ref, which is determined by the code ZQ_code, and the current flowing from the reference node Node_ref to the external resistance R_ext. Thus, the code ZQ_code may have the code value corresponding to the value of the external resistance R_ext.

The reference node Node_ref may be a node that electrically connects the first line Line_1 and the second line Line_2 to one another. The first line Line_1 may be coupled between the pad PAD and the reference node Node_ref. The second line Line_2 may be coupled between the output driver modeling unit 113 and the reference node Node_ref. The pad PAD may be coupled to the external resistance R_ext.

Thus, the voltage level of the reference node Node_ref may be determined depending on the ratio between the current flowing to the reference node Node_ref through the second line Line_2 in accordance with the code value of the code ZQ_code and the current flowing to the external resistance R_ext through the first line Line_1.

That is, the voltage level of the reference node Node_ref may be determined depending on a ratio between a total impedance of the external resistance R_ext and the first line Line_1 and a total impedance of the output driver modeling unit 113 and the second line Line_2.

Therefore, when only the external resistance R_ext and the output driver modeling unit 113 are taken into account in determining the code ZQ_code, the impedance of the first line Line_1 may be the same or substantially the same as the impedance of the second line Line_2. That is, when the length of the first line Line_1 is the same or substantially the same as the length of the second line Line_2, the code ZQ_code may have the code value corresponding to the level of the external resistance R_ext.

As a result, because the first line Line_1 and the second line Line_2 may be formed simultaneously by a single process, the same lengths of the first line Line_1 and the second line Line_2 may mean that the first line Line_1 and the second line Line_2 have the same impedances as one another. The same impedances of the first line Line_1 and the second line Line_2 may provide the code ZQ_code with the code value corresponding to the level of the external resistance R_ext.

According to an example embodiment, the semiconductor device 100 may include the first line Line_1 coupled between the output driver modeling unit 113 and the reference node Node_ref, and the second line Line_2 coupled between the reference node Node_ref and the pad PAD. The length of the first line Line_1 may be the same or substantially the same as the length of the second line Line_2. The code ZQ_code for determining the driving force of the output driver modeling unit 113 may be generated by comparing the voltage level of the reference node Node_ref with the voltage level of the reference voltage Vref.

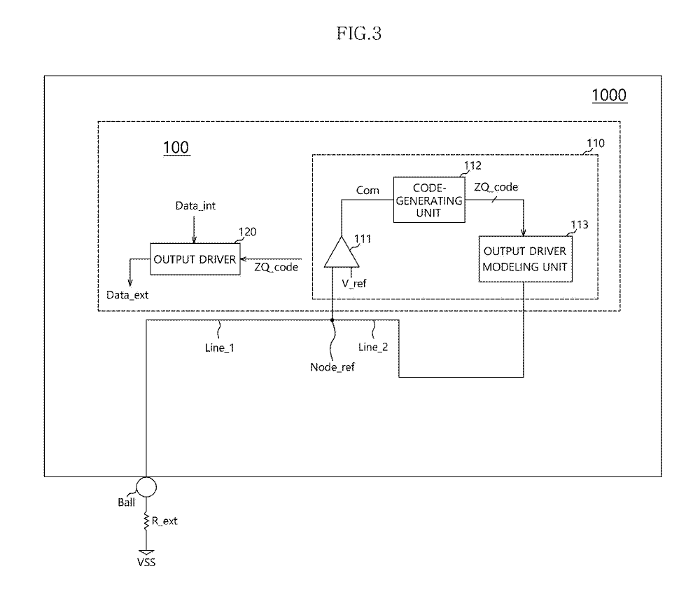

FIG. 3 is a block diagram illustrating a semiconductor package using a semiconductor device in accordance with example embodiments.

Referring to FIG. 3, a semiconductor package in accordance with an embodiment may include a package substrate 1000 and a semiconductor device 100.

The semiconductor device 100 may be arranged on the package substrate 1000. The semiconductor device 100 may be mounted on the package substrate 1000.

The package substrate 1000 may include a ball Ball as an external terminal. The ball Ball may be coupled to the external resistance R_ext.

The semiconductor device 100 may include a comparator 110.

The comparator 110 may include a comparing unit 111, a code-generating unit 112, and an output driver modeling unit 113.

The comparing unit 111 may compare a voltage level of a reference node Node_ref with a voltage level of a reference voltage Vref to generate a comparison signal Com. For example, when the voltage level of the reference node Node_ref is higher than the voltage level of the reference voltage Vref, the comparing unit 111 may enable the comparison signal Com. In contrast, when the voltage level of the reference node Node_ref is lower than the voltage level of the reference voltage Vref, the comparing unit 111 may disable the comparison signal Com.

The code-generating unit 112 may generate a code ZQ_code in response to the comparison signal Com. For example, when the comparison signal Com is enabled, the code-generating unit 112 may increase a code value of the code ZQ_code. In contrast, when the comparison signal Com is disabled, the code-generating unit 112 may decrease a code value of the code ZQ_code.

The output driver modeling unit 113 may adjust a current flowing to the reference node Node_ref or a voltage at the reference node Node_ref in response to the code ZQ_code. For example, the output driver modeling unit 113 may increase the voltage at the reference node Node_ref as the code value of the code ZQ_code decreases, or the output driver modeling unit 113 may increase the current flowing to the reference node Node_ref as the code value of the code ZQ_code decreases. The output driver modeling unit 113 may decrease the voltage at the reference node Node_ref as the code value of the code ZQ_code increases, or the output driver modeling unit 113 may decrease the current flowing to the reference node Node_ref as the code value of the code ZQ_code increases.

The output driver modeling unit 113 in FIG. 3 and the output driver modeling unit 113 in FIG. 1 may have the same or very similar configuration.

The reference node Node_ref may be a node that electrically connects a first line Line_1 and a second line Line_2 to one another. The first line Line_1 may be coupled between the ball Ball and the reference node Node_ref. The second line Line_2 may be coupled between the output driver modeling unit 113 and the reference node Node_ref. The first line Line_1 and the second line Line_2 may be a redistribution layer extended from the ball Ball of the package substrate 1000 to the semiconductor device 100.

In an embodiment, the comparator 110 of the semiconductor device 100 mounted in the semiconductor package may generate the code ZQ_code corresponding to the level of the external resistance R_ext. Thus, the second line Line_2 coupled between the reference node Node_ref and the output driver modeling unit 113 may have a length the same or substantially the same as the length of the first line Line_1. Here, the shape of the second line Line_2 may be different from the shape of the second line Line_2 in FIG. 3.

Hereinafter, operations of the semiconductor package of this example embodiment will be described in detail.

The comparator 110 may generate the code ZQ_code having the code value corresponding to the external resistance R_ext.

The output driver 120 may drive the internal data Data_int using the driving force corresponding to the code value of the code ZQ_code to output the external data Data_ext.

Hereinafter, operations for generating the code ZQ_code by the comparator 110 will be described in detail.

The comparator 110 may include the comparing unit 111, the code-generating unit 112, and the output driver modeling unit 113.

The comparing unit 111 may compare the voltage level of the reference node Node_ref with the voltage level of the reference voltage Vref to generate the comparison signal Com.

The code-generating unit 112 may generate the code ZQ_code in response to the comparison signal Com.

The output driver modeling unit 113 may adjust the current flowing to the reference node Node_ref or the voltage at the reference node Node_ref in response to the code ZQ_code.

The comparator 110 may generate the code value of the code ZQ_code at which the reference voltage Vref has the same value or substantially the same value as the reference node Node_ref. The voltage level of the reference node Node_ref may be determined depending on a ratio between the current flowing to the reference node Node_ref, which is determined by the code ZQ_code, and the current flowing from the reference node Node_ref to the external resistance R_ext. Thus, the code ZQ_code may have the code value corresponding to the value of the external resistance R_ext.

The reference node Node_ref may be a node that electrically connects the first line Line_1 and the second line Line_2 to one another. The first line Line_1 may be coupled between the ball Ball and the reference node Node_ref. The second line Line_2 may be coupled between the output driver modeling unit 113 and the reference node Node_ref. The ball Ball may be coupled to the external resistance R_ext.

Thus, the voltage level of the reference node Node_ref may be determined depending on the ratio between the current flowing to the reference node Node_ref through the second line Line_2 in accordance with the code value of the code ZQ_code and the current flowing to the external resistance R_ext through the first line Line_1.

That is, the voltage level of the reference node Node_ref may be determined depending on a ratio between a total impedance of the external resistance R_ext and the first line Line_1, and a total impedance of the output driver modeling unit 113 and the second line Line_2.

Therefore, when only the external resistance R_ext and the output driver modeling unit 113 are taken into account in determining the code ZQ_code, the impedance of the first line Line_1 is the same or substantially the same as the impedance of the second line Line_2. That is, when the length of the first line Line_1 is the same or substantially the same as the length of the second line Line_2, the code ZQ_code may have the code value corresponding to the level of the external resistance R_ext.

As a result, because the first line Line_1 and the second line Line_2 may be formed simultaneously by a single process, the same lengths of the first line Line_1 and the second line Line_2 may mean that the first line Line_1 and the second line Line_2 have the same impedances as one another. The same impedances of the first line Line_1 and the second line Line_2 may provide the code ZQ_code with the code value corresponding to the level of the external resistance R_ext.

According to an example embodiment, the semiconductor package 1000 may include the first line Line_1 coupled between the ball Ball and the reference node Node_ref, and the second line Line_2 coupled between the reference node Node_ref and the output driver modeling unit 113. The length of the first line Line_1 may be the same or substantially the same as the length of the second line Line_2. The voltage level of the reference node Node_ref may be compared with the voltage level of the reference voltage Vref to generate the code ZQ_code for determining the driving force of the output driver modeling unit 113.

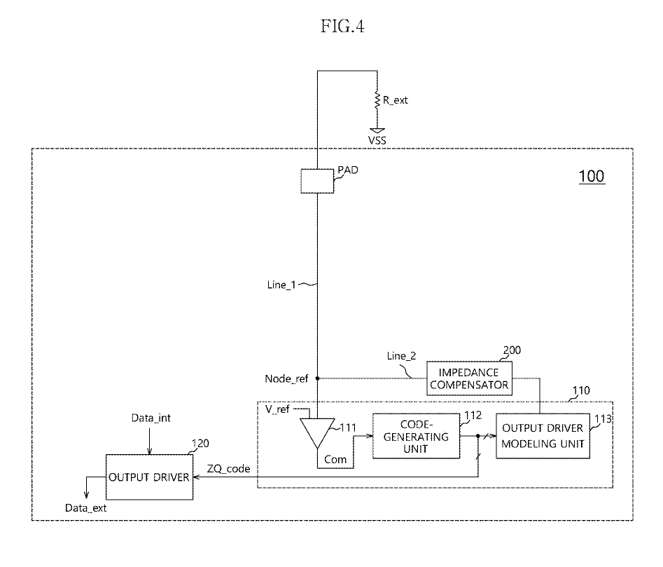

FIG. 4 is a block diagram illustrating a semiconductor device in accordance with example embodiments.

Referring to FIG. 4, a semiconductor device 100 in accordance with an example embodiment may include a comparator 110, an output driver 120, an impedance compensator 200, and a pad PAD. The pad PAD may be coupled to an external resistance R_ext.

The comparator 110 may be coupled to the pad PAD through a first line Line_1.

The pad PAD may be coupled between the first line Line_1 and the external resistance R_ext arranged outside the semiconductor device 100.

The external resistance R_ext may have a first end coupled to the pad PAD and a second end coupled to a ground terminal VSS.

The comparator 110 may include a comparing unit 111, a code-generating unit 112, and an output driver modeling unit 113.

The comparing unit 111 may compare a voltage level of a reference node Node_ref with a voltage level of a reference voltage Vref to generate a comparison signal Com. For example, if the voltage level of the reference node Node_ref is higher than the voltage level of the reference voltage Vref, the comparing unit 111 may enable the comparison signal Com. In contrast, if the voltage level of the reference node Node_ref is lower than the voltage level of the reference voltage Vref, the comparing unit 111 may disable the comparison signal Com.

The code-generating unit 112 may generate a code ZQ_code in response to the comparison signal Com. For example, if the comparison signal Com is enabled, the code-generating unit 112 may increase a code value of the code ZQ_code. In contrast, if the comparison signal Com is disabled, the code-generating unit 112 may decrease a code value of the code ZQ_code.

The output driver modeling unit 113 may adjust a current flowing to the reference node Node_ref or a voltage at the reference node Node_ref in response to the code ZQ_code through the impedance compensator 200 and a second line Line_2. For example, the second line Line_2 may include a line coupled between the reference node Node_ref and the impedance compensator 200, and a line coupled between the impedance compensator 200 and the output driver modeling unit 113. The output driver modeling unit 113 may increase the voltage at the reference node Node_ref as the code value of the code ZQ_code decreases, or the output driver modeling unit 113 may increase the current flowing to the reference node Node_ref as the code value of the code ZQ_code decreases. The output driver modeling unit 113 may decrease the voltage at the reference node Node_ref as the code value of the code ZQ_code increases, the output driver modeling unit 113 may decrease the current flowing to the reference node Node_ref as the code value of the code ZQ_code increases.

The output driver modeling unit 113 in FIG. 4 and the output driver modeling unit 113 in FIG. 1 may have the same or very similar configuration.

The output driver 120 may output internal data Data_int as output data Data_ext in response to the code ZQ_code. For example, the output driver 120 may drive the internal data Data_int using a driving force corresponding to the code value of the code ZQ_code to output the output data Data_ext.

The semiconductor device 100 in FIG. 4 and the semiconductor device in FIG. 2 may have the same or very similar configuration. In contrast, the semiconductor device 100 in FIG. 4 may include the impedance compensator 200 coupled between the reference node Node_ref and the output driver modeling unit 113.

The second line Line_2 coupled between the reference node Node_ref and the output driver modeling unit 113 may have a length the same or substantially the same as the length of the first line Line_1. Further, a total impedance of the second line Line_2 and the impedance compensator 200 may be the same or substantially the same as the impedance of the first line Line_1.

Hereinafter, operations of the semiconductor device 100 of an embodiment will be described in detail.

The comparator 110 may generate the code ZQ_code having the code value corresponding to the external resistance R_ext.

The output driver 120 may drive the internal data Data_int using the driving force corresponding to the code value of the code ZQ_code to output the external data Data_ext.

Hereinafter, operations for generating the code ZQ_code by the comparator 110 will be described in detail.

The comparator 110 may include the comparing unit 111, the code-generating unit 112, and the output driver modeling unit 113.

The comparing unit 111 may compare the voltage level of the reference node Node_ref with the voltage level of the reference voltage Vref to generate the comparison signal Com.

The code-generating unit 112 may generate the code ZQ_code in response to the comparison signal Com.

The output driver modeling unit 113 may adjust the current flowing to the reference node Node_ref or the voltage at the reference node Node_ref in response to the code ZQ_code.

The comparator 110 may generate the code value of the code ZQ_code at which the reference voltage Vref has the same value or substantially the same as the voltage level of the reference node Node_ref. The voltage level of the reference node Node_ref may be determined depending on a ratio between the current flowing from output driver modeling unit 113 to the reference node Node_ref, which is determined the code ZQ_code, and the current flowing from the reference node Node_ref to the external resistance R_ext. Thus, the code ZQ_code may have the code value corresponding to the value of the external resistance R_ext.

The reference node Node_ref may be a node that electrically connects the first line Line_1 and the second line Line_2 to one another. The first line Line_1 may be coupled between the pad PAD and the reference node Node_ref. The second line Line_2 may be coupled between the output driver modeling unit 113 and the reference node Node_ref. The impedance compensator 200 may be arranged on the second line Line_2. The pad PAD may be coupled to the external resistance R_ext.

Thus, the voltage level of the reference node Node_ref may be determined depending on the ratio between the current flowing to the reference node Node_ref through the second line Line_2 and the impedance compensator 200 in accordance with the code value of the code ZQ_code and the current flowing to the external resistance R_ext through the first line Line_1.

That is, the voltage level of the reference node Node_ref may be determined depending on a ratio between a total impedance of the external resistance R_ext and the first line Line_1, and a total impedance of the output driver modeling unit 113, the second line Line_2, and the impedance compensator 200.

Therefore, when only the external resistance R_ext and the output driver modeling unit 113 are taken into account in determining the code ZQ_code, the impedance of the first line Line_1 may be the same or substantially the same as the impedance of the second line Line_2 and the impedance compensator 200. That is, when the impedance of the first line Line_1 is the same or substantially the same as the total impedance of the second line Line_2 and the impedance compensator 200, the code ZQ_code may have the code value corresponding to the level of the external resistance R_ext.

When the impedance of the second line Line_2 is way lower than the impedance of the first line Line_1, the impedance compensator 200 may have an impedance the same or substantially the same as the impedance of the first line Line_1, and the impedance of the second line Line_2 may be disregarded.

According to an example embodiment, the total impedance of the output driver modeling unit 113, the reference node Node_ref, and components and signal lines therebetween may be the same or substantially the same as the total impedance the reference node Node_ref, the pad PAD, and components and signal lines therebetween. The voltage level of the reference node Node_ref may be compared with the voltage level of the reference voltage Vref to generate the code ZQ_code for determining the driving force of the output driver modeling unit 113.

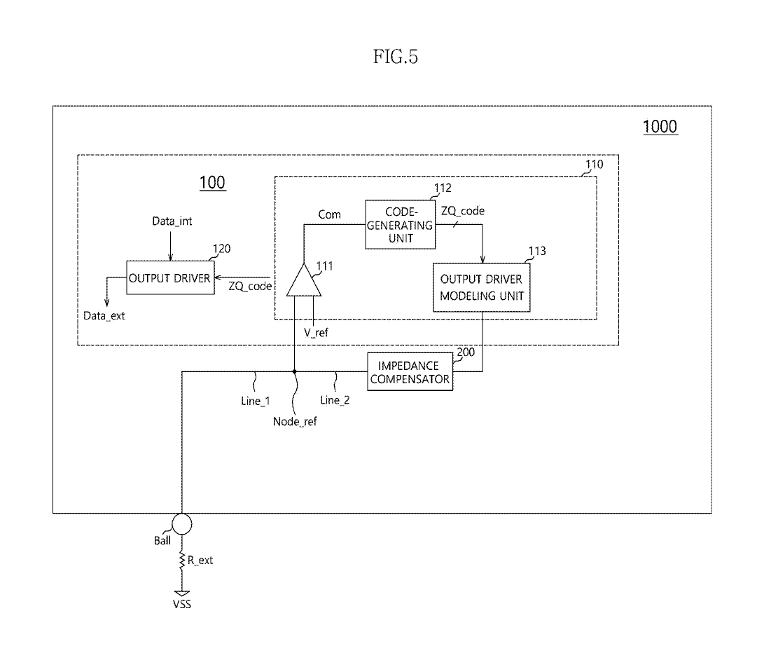

FIG. 5 is a block diagram illustrating a semiconductor package using a semiconductor device in accordance with example embodiments.

Referring to FIG. 5, a semiconductor package of this example embodiment may include a package substrate 1000 and a semiconductor device 100.

The semiconductor device 100 may be arranged on the package substrate 1000. The semiconductor device 100 may be mounted on the package substrate 1000.

The package substrate 1000 may include a ball Ball as an external terminal. The ball Ball may be coupled to the external resistance R_ext.

The semiconductor device 100 may include a comparator 110.

The comparator 110 may include a comparing unit 111, a code-generating unit 112, and an output driver modeling unit 113.

The comparing unit 111 may compare a voltage level of a reference node Node_ref with a voltage level of a reference voltage Vref to generate a comparison signal Com. For example, when the voltage level of the reference node Node_ref is higher than the voltage level of the reference voltage Vref, the comparing unit 111 may enable the comparison signal Com. In contrast, when the voltage level of the reference node Node_ref is lower than the voltage level of the reference voltage Vref, the comparing unit 111 may disable the comparison signal Com.

The code-generating unit 112 may generate a code ZQ_code in response to the comparison signal Com. For example, when the comparison signal Com is enabled, the code-generating unit 112 may increase a code value of the code ZQ_code. In contrast, when the comparison signal Com is disabled, the code-generating unit 112 may decrease a code value of the code ZQ_code.

The output driver modeling unit 113 may adjust a current flowing to the reference node Node_ref or a voltage at the reference node Node_ref through the impedance compensator 200 and the second line Line_2 in response to the code ZQ_code. For example, the output driver modeling unit 113 may increase the voltage at the reference node Node_ref as the code value of the code ZQ_code decreases, or the output driver modeling unit 113 may increase the current flowing to the reference node Node_ref as the code value of the code ZQ_code decreases. The output driver modeling unit 113 may decrease the voltage at the reference node Node_ref as the code value of the code ZQ_code increases, or the output driver modeling unit 113 may decrease the current flowing to the reference node Node_ref as the code value of the code ZQ_code increases.

The output driver modeling unit 113 in FIG. 5 and the output driver modeling unit 113 in FIG. 1 may have the same or very similar configuration.

The reference node Node_ref may be a node that electrically connects a first line Line_1 and a second line Line_2 to another. The first line Line_1 may be coupled between the ball Ball and the reference node Node_ref. The second line Line_2 may include a line coupled between the reference node Node_ref and the impedance compensator 200, and a line coupled between the impedance compensator 200 and the output driver modeling unit 113. The first line Line_1 and the second line Line_2 may be redistribution layers extended from the ball Ball of the package substrate 1000 to the semiconductor device 100.

In an embodiment, the comparator 110 of the semiconductor device 100 mounted in the semiconductor package may generate the code ZQ_code corresponding to the level of the external resistance R_ext. Thus, the second line Line_2 coupled between the reference node Node_ref and the output driver modeling unit 113 may have a length the same or substantially the same as the length of the first line Line_1. Further, the total impedance of the second line Line_2 and the impedance compensator 200 may be the same or substantially the same as the impedance of the first line Line_1. Here, the shape of the second line Line_2 may be different from the shape of the second line Line_2 in FIG. 5.

Hereinafter, operations of the semiconductor package of this example embodiment will be described in detail.

The comparator 110 may generate the code ZQ_code having the code value corresponding to the external resistance R_ext.

The output driver 120 may drive the internal data Data_int using the driving force corresponding to the code value of the code ZQ_code to output the external data Data_ext.

Hereinafter, operations for generating the code ZQ_code by the comparator 110 will be described in detail.

The comparator 110 may include the comparing unit 111, the code-generating unit 112, and the output driver modeling unit 113.

The comparing unit 111 may compare the voltage level of the reference node Node_ref with the voltage level of the reference voltage Vref to generate the comparison signal Com.

The code-generating unit 112 may generate the code ZQ_code in response to the comparison signal Com.

The output driver modeling unit 113 may adjust the current flowing to the reference node Node_ref or the voltage at the reference node Node_ref in response to the code ZQ_code.

The comparator 110 may generate the code value of the code ZQ_code at which the reference voltage Vref has the same value or substantially the same value as the reference node Node_ref. The voltage level of the reference node Node_ref may be determined depending on a ratio between the current flowing to the reference node Node_ref, which is determined by the code ZQ_code, and the current flowing from the reference node Node_ref to the external resistance R_ext. Thus, the code ZQ_code may have the code value corresponding to the value of the external resistance R_ext.

The reference node Node_ref may be a node that electrically connects the first line Line_1 and the second line Line_2 to one another. The first line Line_1 may be coupled between the ball Ball and the reference node Node_ref. The second line Line_2 may be coupled between the output driver modeling unit 113 and the impedance compensator 200, and between the impedance compensator 200 and the reference node Node_ref. The ball Ball may be coupled to the external resistance R_ext.

Thus, the voltage level of the reference node Node_ref may be determined depending on the ratio between the current flowing to the reference node Node_ref through the second line Line_2 and the impedance compensator 200 in accordance with the code value of the code ZQ_code and the current flowing to the external resistance R_ext through the first line Line_1.

That is, the voltage level of the reference node Node_ref may be determined depending on a ratio between a total impedance of the external resistance R_ext and the first line Line_1, and a total impedance of the output driver modeling unit 113, the second line Line_2 and the impedance compensator 200.

Therefore, when only the external resistance R_ext and the output driver modeling unit 113 are taken into account in determining the code ZQ_code, the impedance of the first line Line_1 is the same or substantially the same as the impedance of the second line Line_2. That is, when the impedance of the first line Line_1 is the same or substantially the same as the total impedance of the second line Line_2 and the impedance compensator 200, the code ZQ_code may have the code value corresponding to the level of the external resistance R_ext.

When the impedance of the second line Line_2 may be way lower than the impedance of the first line Line_1, the impedance compensator 200 may have an impedance the same or substantially the same as the impedance of the first line Line_1, and the impedance of the second line Line_2 may be disregarded.

According to an example embodiment, the total impedance of the ball Ball, the reference node Node_ref, and components and signal lines therebetween may be the same or substantially the same as the impedance of the reference node Node_ref, the output driver modeling unit 113, and components and signal lines therebetween. The voltage level of the reference node Node_ref may be compared with the voltage level of the reference voltage Vref to generate the code ZQ_code for determining the driving force of the output driver modeling unit 113.

Thus, in various embodiments of the present invention, the total impedance of all the components and signal lines connected from the output driver modeling unit to the reference node may be the same or substantially the same as the total impedance of all the components and signal lines connected from the reference node to the external resistance in the semiconductor devices and the semiconductor packages except for the output driver modeling unit and the external resistance. As a result, it is possible to generate the code by considering only the output driver modeling unit and the external resistance.

While various embodiments have been described above, it will be understood to those skilled in the art that the embodiments described are by way of example only. Accordingly, the circuit and method described herein should not be limited based on the described embodiments.

What is claimed is:

1. A semiconductor device comprising:
a comparator configured to compare a voltage level of a reference node with a voltage level of a reference voltage to generate a code, the comparator including an output driver modeling unit configured to adjust a current flowing to the reference node depending on a code value of the code to the reference node; and
a pad coupled to the reference node,
wherein a total impedance of the reference node, the output driver modeling unit, and components and signal lines coupled therebetween corresponds to a total impedance of the reference node, the pad, and components and signal lines coupled therebetween.

2. The semiconductor device of claim 1, further comprising an impedance compensator coupled between the reference node and the output driver modeling unit, the impedance compensator having an impedance the same or substantially the same as the total impedance of the reference node, the pad, and components and signal lines coupled therebetween.

3. The semiconductor device of claim 1, wherein the reference node is coupled to the pad through a first line, the output driver modeling unit is coupled to the reference node through a second line, and the first line has a length the same or substantially the same as a length of the second line.

4. The semiconductor device of claim 1, wherein the comparator comprises:
a comparing unit configured to compare the voltage level of the reference node with the voltage level of the reference voltage to generate a comparison signal;
a code-generating unit configured to generate the code in response to the comparison signal; and
the output driver modeling unit configured to adjust the current flowing to the reference node in response to the code.

5. The semiconductor device of claim 1, further comprising an output driver configured to determine a driving force in response to the code and output data using the driving force.

6. The semiconductor device of claim 1, wherein the pad is coupled to an external resistance.

7. A semiconductor package comprising:
a package substrate; and
a semiconductor device arranged on the package substrate;
a reference node configured to be used in comparing impedances at different nodes;
an external terminal formed on package substrate to electrically connect the semiconductor devices to external devices; and
an impedance compensator coupled between the reference node and the semiconductor device, wherein a total impedance of components and signal lines coupled between the reference node and the semiconductor device corresponds to a total impedance of components and signal lines coupled between the external terminal and the reference node.

8. The semiconductor package of claim 7, wherein the impedance compensator has an impedance the same or substantially the same as the total impedance of components and signal lines coupled between the reference node and the external terminal.

9. The semiconductor package of claim 7, wherein the reference node is coupled to the external terminal through a first line, the semiconductor device is coupled to the reference node through a second line, and the first line has a length the same or substantially the same as a length of the second line.

10. The semiconductor package of claim 7, wherein the semiconductor device comprises a comparator configured to compare a voltage level of a reference node with a voltage level of a reference voltage to generate a code, and adjust a current flowing to the reference node depending on a code value of the code.

11. The semiconductor package of claim 10, wherein the comparator comprises:
a comparing unit configured to compare the voltage level of the reference node with the voltage level of the reference voltage to generate a comparison signal;
a code-generating unit configured to generate the code in response to the comparison signal; and
an output driver modeling unit configured to adjust a current flowing to the reference node in response to the code.

12. The semiconductor package of claim 7, wherein external terminal include a ball coupled to an external resistance.

13. A semiconductor device comprising:
a reference node configured to be used in comparing impedances at different nodes;
an external terminal configured to provide an electrical connection to external devices;
a comparing unit configured to compare a voltage level of the reference node with a voltage level of a reference voltage to generate a code;
an output driver modeling unit configured to adjust a current flowing to the reference node in response to the code; and
an impedance compensator coupled between the reference node and a target object of impedance matching, wherein a total impedance of components and signal lines coupled between the reference node and the target object of impedance matching corresponds to a total impedance of components and signal lines coupled between the external terminal and the reference node.

14. The semiconductor package of claim 13, wherein the impedance compensator has an impedance the same or substantially the same as the total impedance of components and signal lines coupled between the reference node and the external terminal.

15. The semiconductor package of claim 13, wherein the reference node is coupled to the external terminal through a first line, the target object of impedance matching is coupled to the reference node through a second line, and the first line has a length the same or substantially the same as a length of the second line.
